(19) United States
(12) Patent Application Publication
(10) Pub. No.: US 2006/0223211 A1
(43) Pub. Date: Oct. 5, 2006

(54) Semiconductor devices based on coalesced nano-rod arrays

(75) Inventors: Umesh Kumar Mishra, Montecito, CA (US); Stacia Keller, Santa Barbara, CA (US)

Correspondence Address: GATES & COOPER LLP;HOWARD HUGHES CENTER, 6701 CENTER DRIVE WEST, SUITE 1050, LOS ANGELES, CA, 90045, US

(73) Assignee: The Regents of the University of California

(21) Appl. No.: 11/292,527

(22) Filed: Dec. 2, 2005

Related U.S. Application Data
(60) Provisional application No. 60/632,594, filed on Dec. 2, 2004.

(51) Int. Cl. H01L 21/00

(52) U.S. Cl. 438/41; 438/44; 438/39

(57) ABSTRACT

Semiconductor devices are fabricated using semiconductor nano-rod arrays, which are merged through coalescence into a continuous planar layer after the nano-rods in the nano-rod array are fabricated by growth or etching. Merging of the nano-rods through coalescence into a continuous layer is achieved by tuning the growth conditions into a regime allowing epitaxial lateral overgrowth.

### CROSS-REFERENCE TO RELATED APPLICATION

This application claims the benefit under 35 U.S.C. §119(e) of the following co-pending and commonly-assigned application:

U.S. Provisional Application Ser. No. 60/632,594, filed on Dec. 2, 2004, by Umesh K. Mishra and Stacia Keller, entitled “SEMICONDUCTOR DEVICES BASED ON COALESCED NANO-ROD ARRAYS,” attorneys' docket number 30794.125-US-P1(2005-218-1); which application is incorporated by reference herein.

### STATEMENT REGARDING SPONSORED RESEARCH AND DEVELOPMENT

The present invention was made under support from the University of California, Santa Barbara Solid State Lighting and Display Center member companies, including Stanley Electric Co., Ltd., Mitsubishi Chemical Corp., Rohm Co., Ltd., Cree, Inc., Matsushita Electric Works, Matsushita Electric Industrial Co., and Seoul Semiconductor Co., Ltd.

### BACKGROUND OF THE INVENTION

1. Field of the Invention

The present invention relates to semiconductor devices based on coalesced nano-rod arrays.

2. Description of the Related Art

(Note: This application references a number of different publications as indicated throughout the specification by reference numbers enclosed in brackets, e.g., [x]. A list of these different publications ordered according to these reference numbers can be found below in the section entitled “References. ” Each of these publications is incorporated by reference herein.)

In the prior art, nanoscale devices have been fabricated following two different approaches. In the most common approach, the growth and arrangement of semiconductor nano-rods (also known as nano-wires) are performed using separate processes. In a first step, the nano-wires are synthesized predominantly using the vapor-liquid-solid (VLS) process. In a second step, the nano-wires are immersed into a solution and transferred onto a substrate (mostly silicon), which is pre-patterned with metal contacts, allowing current injection into individual selected wires. By this means, nano-wire transistors and light emitting diodes (LEDs) have been demonstrated. Using this approach, wire growth, wire transfer to the substrate and actual device selection are very complicated, and the probability of a successful wire positioning is low. Consequently, the approach is well suited for demonstration purposes, but is not attractive for device fabrication in an industrial setting. [3,4]

In an alternate approach, devices are comprised of semiconductor whisker arrays, which are grown on a template either by the VLS technique, random positioning or selective area growth. After deposition of the semiconductor material, such structures are buried in spin-on glass (SOG) to planarize the wafer prior to subsequent processing of the device. This procedure, however, requires the deposition of whiskers with heights in the order of one micrometer to reach the nanoscale diameter required for the deposition of the active region of the device. In addition, contact resistances are very high because of the extremely small contact area between the whisker tip and the contact metal. [5,6,7]

What is needed are improved techniques that overcome previous disadvantages in the way that the nano-wires or nano-rods are pre-positioned on the substrate in arrays using lithographic techniques. The present invention satisfies that need.

### SUMMARY OF THE INVENTION

The present invention describes a method for fabricating semiconductor devices using semiconductor nano-rod arrays, wherein nano-rods in the nano-rod array are merged through coalescence into a continuous planar layer after fabrication by growth or etching. Merging of the nano-rods through coalescence into a continuous layer is achieved by tuning the growth conditions into a regime allowing epitaxial lateral overgrowth.

### BRIEF DESCRIPTION OF THE DRAWINGS

Referring now to the drawings in which like reference numbers represent corresponding parts throughout:

FIGS. 1A and 1B are cross-section side views of examples of nano-rod-array-based (Al,Ga,In)N light emitting diodes (LEDs) according to the preferred embodiment of the present invention;

FIG. 2 is a flowchart that illustrates a fabrication by growth procedure for the nano-rod-array-based (Al,Ga,In)N light emitting diode (LED) according to one embodiment of the present invention;

FIGS. 3A and 3B are cross-section side views of examples of nano-rod-array-based (Al,Ga,In)N light emitting diodes (LEDs) according to the preferred embodiment of the present invention, including an epitaxial distributed Bragg reflector (DBR) stack incorporated on an n-side of the structure for resonant cavity devices, as shown in FIG. 3A, and a second distributed Bragg reflector (DBR) added on a p-side for a vertical cavity surface emitting laser (VCSEL), as shown in FIG. 3B;

FIGS. 4A, 4B, 4C and 4D are cross-section side views that illustrates the fabrication of a nano-rod-array-based (Al,Ga,In)N LED according to the preferred embodiment of the present invention;

FIG. 5 is a flowchart that illustrates a fabrication by etching procedure for the nano-rod-array-based (Al,Ga,In)N LED according to one embodiment of the present invention.

FIGS. 6A-C illustrate the fabrication steps of an alternative embodiment of the present invention where the active region is protected by capping it with a material layer with higher bandgap than the quantum well;

FIGS. 7A-D illustrate the fabrication steps performed in another alternative embodiment of the present invention where an SiO₂ layer is deposited before the capping layer;

FIGS. 8A-C illustrate the fabrication steps performed in yet another alternative embodiment of the present invention where the nano-rods comprise pillars with non-planar tips; and

FIGS. 9A-B illustrate the fabrication steps performed in still another alternative embodiment of the present invention where the nano-rods are wafer-bonded to another wafer or substrate.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

Semiconductor devices are fabricated using semiconductor nano-rod arrays, wherein the nano-rods are fabricated by growth or etching, and then are coalesced or merged into a continuous planar layer. This approach combines the advantages of nanostructures, which allow the combination of materials with large lattice mismatch while maintaining high crystalline perfection, with the simplicity of device processing for planar epitaxial layers, thereby significantly widening device design opportunities. In addition, this method allows for a significant reduction in contact resistance. Merging of the nano-rods through coalescence into a continuous layer is achieved by tuning the growth conditions into a regime allowing epitaxial lateral overgrowth. The nano-rod concept can be applied to all devices that are based on vertical current injection, such as LEDs and laser diodes (LDs).

Technical Description

The present invention enables the combination of nano-technology and large area fabrication of opto-electronic and electronic devices. Specifically, the present invention overcomes previous disadvantages in the way that the nano-rods are pre-positioned on the substrate in arrays using lithographic techniques. After completion of the nano-rod growth or etching, the growth conditions are modified to coalesce or merge the individual rods into one continuous planar layer. All post nano-rod device fabrication steps can then be performed using standard planar processing techniques. In addition, the planar contact layer minimizes the resistance in the devices.

The advantages of the nano-rod arrays over conventional large area epitaxial approaches are:
The nano-rods are dislocation free. Due to the close vicinity of the free surface, dislocations, which may exist in the underlying substrate, bend towards the walls of the nano-rods in their initial stage of growth and do not propagate into the active region of the structure. This is, in particular, of interest for group III nitrides, as low dislocation density substrates are still not commercially available.
The nanoscale nature of the nano-rods significantly reduces restrictions related to lattice matching of the individual layers within the nano-rods and significantly widens the device design opportunities.
The high surface area of the nano-rods and the simultaneous presence of crystal surfaces with different orientation affect polarization effects in the structures and therefore allow the observation and utilization of new phenomena, in particular in the case of group-III nitrides.
The structures are scalable to large wafer diameters. Since all planar layers in the device structures can be very thin, the influence of thermal mismatch between epitaxial structure and the substrate on the wafer bowing is minimized.
The nano-rod array can be arranged as a photonic crystal for light extraction engineering.

The present invention is especially attractive for devices made from materials for which homoepitaxy is not possible, as single crystalline, lattice matched substrates are still not commercially available, as, for instance, for GaN, AlN, InN and their alloys.

Group-III nitrides are typically deposited on SiC, sapphire or Si substrates. The heteroepitaxial growth process, however, leads to the formation of defects/dislocations that hamper device performance. The present invention allows the growth of dislocation free nano-rod material, independent of the lattice constant of the substrate.

Fabrication By Growth

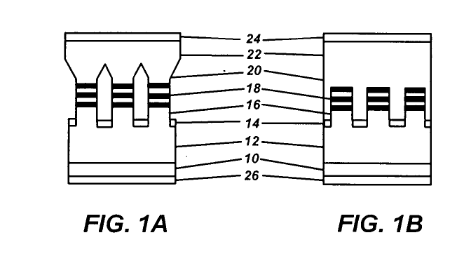

FIGS. 1A and 1B are cross-section side views of examples of nano-rod-array-based (Al,Ga,In)N LEDs. The LEDs each includes an SiC substrate 10, n-type GaN:Si layer 12, SiO₂ layer 14, n-type semiconductor nano-rods 16, InGaN/GaN quantum well (QW) active region 18, p-type GaN:Mg layer 20, coalesced p-type GaN:Mg layer 22, p-type (transparent) metal contacts 24 and n-type metal contacts 26.

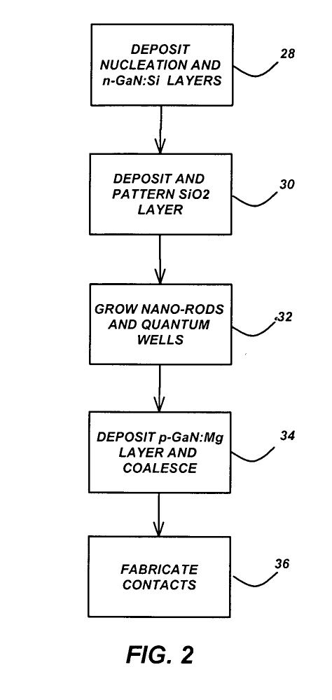

FIG. 2 is a flowchart that illustrates a method of fabricating a semiconductor device by merging semiconductor nano-rods 16 in a nano-rod 16 array through coalescence into a continuous planar layer after fabrication of the nano-rods 16, wherein the nano-rods 16 are fabricated by growth and the merging step comprises merging the nano-rods 16 through coalescence into the continuous planar layer by tuning conditions to promote epitaxial lateral overgrowth. Specifically, the nano-rods 16 are grown on top of an n-type layer 12, an active region 18 is deposited on top of the nano-rods 16, and a p-type layer 20 is grown on top of the active region 18, wherein the p-type layer 20 is coalesced 22 into the continuous planar layer.

For the fabrication of group-III nitride devices, the nano-rod 16 growth should be preferentially carried out on nitrogen polar (000-1) GaN templates, or if the nano-rod 16 growth is initiated directly on a substrate 10 (patterned or random), the substrate 10 and the growth conditions should lead to group III-nitride nano-rod 16 growth along the [000-1] direction.

The fabrication by growth procedure includes the following steps:

(a) Block 28 represents depositing a thin, conducting (Al,Ga)N nucleation layer on a conducting carbon face {000-1} SiC substrate or wafer 10 in a growth chamber, followed by a deposition of an approximately 0.5 μm thick n-type GaN:Si layer 12 using, for example, metalorganic chemical vapor deposition (MOCVD).

(b) Block 30 represents removing the substrate 10 from the growth chamber and depositing a thin (30 nm) SiO₂ layer 14 onto the n-type GaN:Si layer 12, wherein the SiO₂ layer 14 is a masking layer that is then patterned using lithographic techniques, for example, electron-beam lithography, followed by etching, to create a desired array of nanometer size openings in the SiO₂ layer 14.

(c) Block 32 represents transferring the patterned substrate 10 back into the growth chamber, and selectively growing n-type semiconductor nano-rods 16 in the array of openings, followed by growing an InGaN/GaN QW active region 18 on the n-type semiconductor nano-rods 16.

(d) Block 34 represents growing a p-type GaN:Mg layer 20 with a larger band gap than the QW active region 18 on top of the QW active region 18, wherein, during the growth of the p-type GaN:Mg layer 20, deposition conditions enhance lateral growth and coalescence of the p-type GaN:Mg layer 20, as indicated by 22, thereby merging the nano-rods 16 through coalescence into a continuous planar layer.

(e) Finally, in Block 36, p-type (transparent) metal contacts 24 and n-type metal contacts 26 are fabricated on the device using standard device processing procedures for planar devices.

The fabrication procedure can be modified in such a way that the process is interrupted after the deposition of the QW active region 18 or after growth of the thin p-type GaN:Mg layer 20 (which caps the nano-rods 16). The substrate 10 is then taken out of the growth chamber and a passivation material is deposited onto the substrate 10 to fill into the gaps between the nano-rods 16. Excess passivation material is removed from the surface and the substrate 10 re-inserted into the growth chamber to complete the deposition of the p-type GaN:Mg layer 20 in Block 34.

In another modification, the p-type GaN:Mg layer 20 on top of the QW active region 18 is deposited in such a way that it completely fills into the gaps between the nano-rods 16, as illustrated in FIG. 1B. As a result, the composition of the layers 20 can be chosen in such a way that optimum optical confinement of photons in the nano-rods 16 is achieved.

In another modification, the p-type GaN:Mg layer 20, 22 on top of the active region 18 is replaced by a p-n tunnel junction. By this means, difficulties in the fabrication of p-type contacts 24 can be eliminated. This is in particular of interest for devices utilizing AlGaN layers with high Al-content.

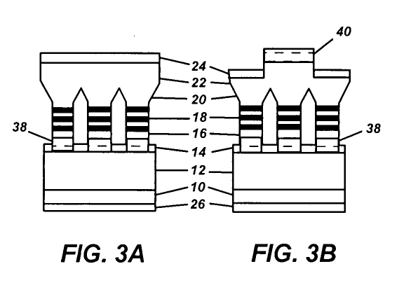

In another modification, an epitaxial distributed Bragg reflector (DBR) stack 38 is incorporated on the n-side of the structure for resonant cavity devices, as shown in FIG. 3A, which is a cross-section side view of a variation of the nano-rod-array-based GaN resonant cavity LED.

In yet another modification, if a second DBR 40 is added on the p-side of the structure, then a vertical cavity surface emitting laser (VCSEL) can be fabricated, as shown in FIG. 3B, which is a cross-section side view of a nano-rod-array-based VCSEL. The DBR 40 on top of the p-type GaN:Mg layer 20, 22 could be a dielectric stack deposited by e-beam lithography. Independent of the fabrication process, the p-side DBR 40 can be deposited on the already planarized wafer, wherein mesa etching is then performed to contact the p-type GaN:Mg layer 20, 22 beneath the DBR 40.

Variations and Modifications

Some possible variations and modifications to the fabrication by growth procedure include the following:
The substrate 10 can be silicon, sapphire, spinel, lithium aluminate, ZnO, etc.
The nano-rod 16 growth can be initiated on an epitaxial layer as described above, or directly on a substrate 10. Thereby, the growth can be either seeded randomly, using the VLS technique, or the nano-rod 16 arrangement can be defined using lithographic techniques as described in Block 30, or the nano-rod 16 arrangement can be defined by other techniques, such as thin porous alumina films.
The nano-rods 16 can be grown along any crystallographic direction.
The nano-rods 16 can be formed from all group IV, III-V and II-VI semiconductor materials including oxides, as well as other oxide materials, for example, from the Indium Tin Oxide (ITO) group
The p-type layer 20, 22 of the structure can be made from non-single crystalline material and deposited in a separate chamber.
The layer sequence in the nano-rods 16 can be varied according to the nature of the anticipated device. Generally, the nano-rod 16 array concept can be applied to any vertical device structure, such as lasers, bipolar transistors, etc.
The nano-rod 16 growth can be performed by any epitaxial growth technique, for example, molecular beam epitaxy (MBE), chemical beam epitaxy (CBE), chloride assisted MOCVD, etc.
The nano-rod 16 arrays can be replaced by arrays of nano-stripes for device structures that are comprised of layers with medium lattice mismatch. The use of nano-stripes instead of nano-rods 16 allows the use of a wider range of crystallographic growth directions, thereby allowing coalescence of the individual features in the final stage of epitaxial growth. Furthermore, coalesced nano-stripe arrays can also be utilized for devices relying on lateral carrier transport, such as, for example, field effect transistors.
The growth of the nano-rod 16 array can be stopped after deposition of the active region 18, and the device structure could be completed through wafer bonding, as in the case for etched structures described below.

Fabrication By Etching

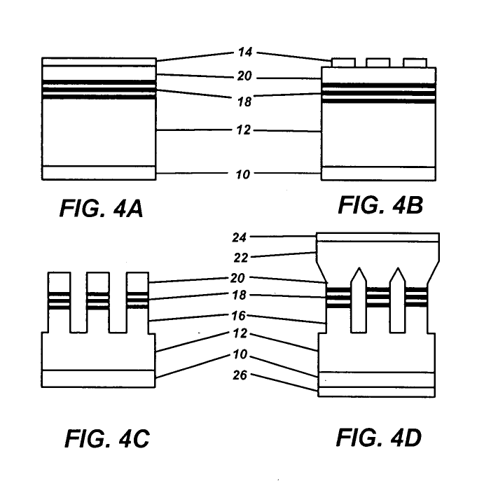

FIGS. 4A, 4B, 4C and 4D are cross-section side views that illustrates the fabrication steps for a nano-rod-array-based (Al,Ga,In)N LED. The LED includes an SiC substrate 10, n-type GaN:Si layer 12, SiO₂ layer 14, n-type semiconductor nano-rods 16, InGaN/GaN QW active region 18, p-type GaN:Mg layer 20, coalesced p-type GaN:Mg layer 22, p-type (transparent) metal contacts 24 and n-type metal contacts 26.

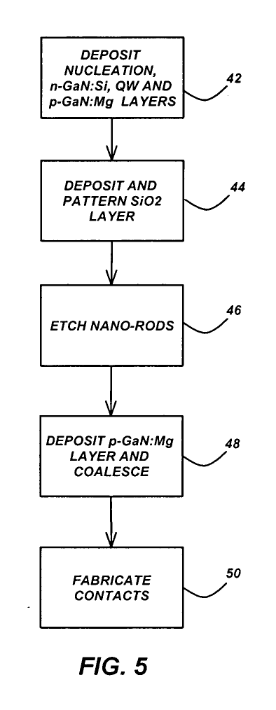

FIG. 5 is a flowchart that illustrates a method of fabricating a semiconductor device by merging semiconductor nano-rods 16 in a nano-rod 16 array through coalescence into a continuous planar layer after fabrication of the nano-rods 16, wherein the nano-rods 16 are fabricated by etching and the merging step comprises merging the nano-rods 16 through coalescence into the continuous planar layer by tuning conditions to promote epitaxial lateral overgrowth. Specifically, the nano-rods 16 are etched from an initially planar epitaxial structure comprised of an n-type layer 12, an active region 18 deposited on top of the n-type layer 12, and a p-type layer 20 grown on top of the active region 18. The method further comprises annealing the etched nano-rods 16, wherein the p-type layer 20 is coalesced 22 into the continuous planar layer after the nano-rods 16 are annealed.

This procedure is an alternative to the growth of nano-rods 16, wherein nano-rods 16 can be fabricated through etching of an initially planar epitaxial structure. The properties of the etched nano-rods 16 significantly improve, in particular, after subsequent annealing of the etched nano-rods 16. Following the annealing, the nano-rods 16 can than be coalesced 22 again, as described in the fabrication by growth procedure.

The fabrication by etching procedure includes the following steps:

(a) Block 42 represents depositing a thin, conducting (Al,Ga)N nucleation layer on a conducting SiC substrate or wafer 10 in a growth chamber, followed by a deposition of an approximately 1μm thick n-type GaN:Si layer 12, InGaN/GaN QW wells 18, an optional AlGaN electron blocking layer (not shown), and an optional thin p-type GaN:Mg layer 20, on the conducting SiC substrate 10. This step may use, for example, metalorganic chemical vapor deposition (MOCVD). The resulting structure is shown in FIG. 4A.

(b) Block 44 represents removing the substrate 10 from the growth chamber and depositing a thin (30 nm) SiO₂ layer 14 onto the substrate 10, wherein the SiO₂ layer 14 is a masking layer that is then patterned using lithographic techniques to create an array of openings in the SiO₂ layer 14. The resulting structure is shown in FIG. 4B.

(c) Block 46 represents transferring the patterned substrate 10 into an etching chamber, and forming n-type semiconductor nano-rods 16 in the array of openings. The resulting structure is shown in FIG. 4C.

(d) Block 48 represents transferring the substrate 10 back into the growth chamber and depositing a p-GaN:Mg layer 20 on the n-type semiconductor nano-rods 16, wherein, during the growth of the p-type GaN:Mg layer 20, deposition conditions promote lateral growth and coalescence of the p-type GaN:Mg layer 20, as indicated by 22, thereby merging the nano-rods 16 through coalescence into a continuous planar layer.

(e) Finally, in Block 50, n-type and p-type contacts 24, 26 are fabricated for the device using standard device processing procedures for planar devices. The resulting structure is shown in FIG. 4D.

Variations and Modifications

The fabrication by etching procedure can be modified in such a way, that, in Block 48 above, the etched wafer 10 is first annealed under specific conditions prior to deposition of the p-GaN layer 20.

Other possible variations and modifications include:
The substrate 10 can be silicon, sapphire, spinel, lithium aluminate, ZnO, etc.
The nano-rods 16 can be formed from all group IV, III-V and II-VI semiconductor materials, including oxides, as well as other oxide materials, for instance, from the Indium Tin Oxide (ITO) group.
The p-type layers 20, 22 of the structure can be made from non-single crystalline material and deposited in the separate chamber.
The layer sequence in the nano-rods 16 can be varied according to the nature of the anticipated device. Generally, the nano-rod 16 array concept can be applied to any vertical device structure, such as lasers, bipolar transistors, etc.
The nano-rod 16 array fabrication by etching and growth can be combined in such a way that the nano-rods 16 are first defined by etching, but the QW active region 18 is then grown on top of the pre-defined pillars, followed by the p-GaN layer 20, 22.
As described above, the nano-rod 16 array can be replaced by a nano-stripe array for device structures.
The fabrication steps can be also conducted in such a way that the entire p-layer 20, 22 is grown after etching, instead of depositing an initial thin p-type GaN:Mg layer 20 prior to etching as described above.
Note also that other masking materials can be used, as well as other procedures.

Alternative Embodiments

Alternative embodiments may include further possible modifications. For example, the diameter of the nano-rods 16 affect their emission wavelength. Consequently, either an opening diameter for the nano-rods 16 or a diameter defined by etching may be chosen in such away that the individual nano-rods 16 emit light of different color resulting in white light emission from the entire array of nano-rods 16. Moreover, several nano-rods 16 of constant diameter can be grouped together to minimize interactions of nano-rods 16 with different diameter and emission wavelength. In addition, this concept can be applied to any crystal orientation.

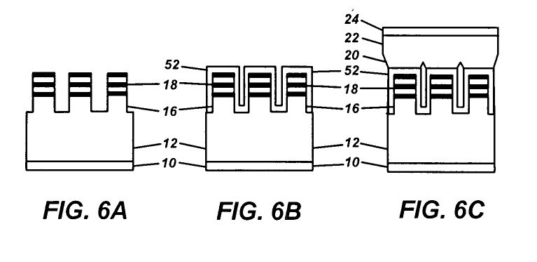

FIGS. 6A-C illustrate the fabrication steps of an alternative embodiment of the present invention. As shown in FIG. 6A, the fabrication steps of the alternative embodiment begin when the LED is comprised the SiC substrate 10, n-type GaN:Si layer 12, n-type semiconductor nano-rods 16 and InGaN/GaN QW active region 18. To prevent damage of the active region 18 through annealing or growth of the Mg-doped p-layer 20, the active region 18 is protected by a capping layer 52 comprised of a material with a higher bandgap than the active region 18, for example, AlGaN. The deposition of the layer 52 is shown in FIG. 6B. The nano-rods 16 may be entirely covered and the higher bandgap layer 52 simultaneously used as an electron blocking layer. Thereafter, as shown in FIG. 6C, a p-GaN:Mg layer 20 is deposited on the layer 52, wherein, during the growth of the p-type GaN:Mg layer 20, deposition conditions promote lateral growth and coalescence of the p-type GaN:Mg layer 20, as indicated by 22, thereby merging the nano-rods 16 through coalescence into a continuous planar layer. Finally, an n-type contact 24 and p-type contact 26 (not shown) may be fabricated for the device using standard device processing procedures for planar devices.

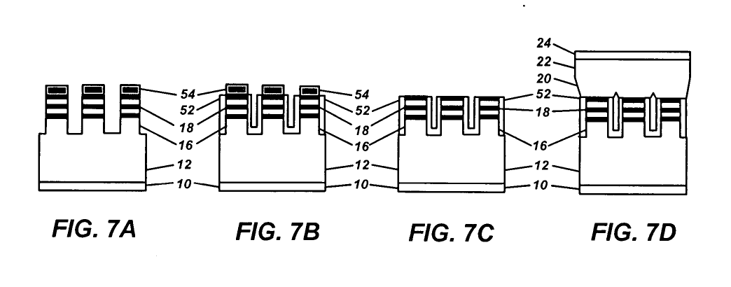

FIGS. 7A-D illustrate the fabrication steps performed in another alternative embodiment of the present invention. As shown in FIG. 7A, the fabrication steps of the alternative embodiment begin when the LED is comprised the SiC substrate 10, n-type GaN:Si layer 12, n-type semiconductor nano-rods 16 and InGaN/GaN QW active region 18, wherein an SiO₂ layer 54 is deposited on top of the nano-rods 16 before the capping layer 52. The higher bandgap layer 52 is deposited, as shown in FIG. 7B, and then the SiO₂ layer 54 is removed, as shown in FIG. 7C. As a result, the tops of the nano-rods 16 are not covered by the capping layer 18, yet the active region 18 is still protected by the capping layer 18. Thereafter, as shown in FIG. 7D, a p-GaN:Mg layer 20 is deposited both on the layer 52 and on the nano-rods 16, wherein, during the growth of the p-type GaN:Mg layer 20, deposition conditions promote lateral growth and coalescence of the p-type GaN:Mg layer 20, as indicated by 22, thereby merging the nano-rods 16 through coalescence into a continuous planar layer. Finally, an n-type contact 24 and p-type contact 26 (not shown) may be fabricated for the device using standard device processing procedures for planar devices. Thus, in this embodiment, capping and p-n junction engineering are performed independently.

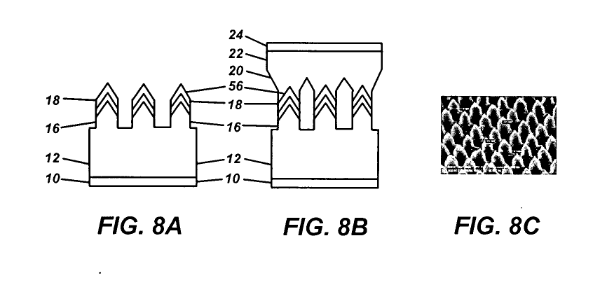

FIGS. 8A-C illustrate the fabrication steps performed in yet another alternative embodiment of the present invention. As shown in FIG. 8A, the fabrication steps of the alternative embodiment begin when the LED is comprised the SiC substrate 10, n-type GaN:Si layer 12, n-type semiconductor nano-rods 16 and InGaN/GaN QW active region 18, wherein the nano-rods 16 comprise pillars with non-planar tips 56, such as stripes with non-planar ridge tops, possessing non-polar or semi-polar surfaces, which form easily under specific growth conditions. Thereafter, as shown in FIG. 8B, a p-GaN:Mg layer 20 is deposited both on the nano-rods 16, wherein, during the growth of the p-type GaN:Mg layer 20, deposition conditions promote lateral growth and coalescence of the p-type GaN:Mg layer 20, as indicated by 22, thereby merging the nano-rods 16 through coalescence into a continuous planar layer. Finally, an n-type contact 24 and p-type contact 26 (not shown) may be fabricated for the device using standard device processing procedures for planar devices. Note that FIG. 8C is an atomic force microscopy (AFM) image showing the non-planar tips 56 of the nano-rods 16.

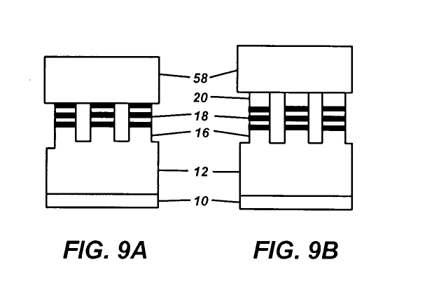

Finally, FIGS. 9A-B illustrate the fabrication steps performed in still another alternative embodiment of the present invention. As shown in both FIGS. 9A and 9B, the fabrication steps of the alternative embodiment begin when the LED is comprised the SiC substrate 10, n-type GaN:Si layer 12, n-type semiconductor nano-rods 16 and InGaN/GaN QW active region 18. Thereafter, the nano-rods 16 are wafer-bonded to another wafer or substrate 58, which may be comprised of GaN:Mg or ZnO, for example. In FIG. 9A, the wafer-bonding of 58 is performed directly on the nano-rods 16, while in FIG. 9B, the wafer-bonding of 58 is performed on the p-type GaN:Mg layer 20.

### REFERENCES

The following references are incorporated by reference herein:

[1] R. S. Wagner,“VLS Mechanism of Crystal Growth,” Whisker Technology, ed. A. P. Levitt, Wiley, New York, 1970, pp. 47-133.

[2] M. S. Gudiksen, L. J. Lauhon, J. Wang, D. C. Smith, and C. M. Lieber,“Growth of nano-wire superlattice structures for nanoscale photonics and electronics,” Nature, 415, 2002, pp. 617-620.

[3] Y. Huang, X. Duan, Q. Wei, and C. M. Lieber,“Direct Assembly of One-Dimensional nanostructures into Functional Networks,” Science, 291, 2001, pp. 630-633.

[4] X. Duan, Y. Huang, R. Agarwal, and C. M. Lieber,“Single-nano-wire electrically driven lasers,” Nature, 421, 2003, pp. 241-245.

[5] K. Hiruma, M. Yazawa, T. Katsuyama, K. Ogawa, K. Haraguchi, M. Koguchi, H. Kakibayashi, “Growth and optical properties of nanometer-scale GaAs and InAs whiskers,” J. Appl. Phys. 77, 1995, p. 447.

[6] U.S. Pat. No. 5,332,910, issued Jul. 26, 1994, to Haraguchi et al., and entitled “Semiconductor optical device with nanowhiskers.”

[7] H. M. Kim, Y. H. Cho, H. Lee, S. I. Kim, S. R. Ryu, D. Y. Kim, T. W. Kang, K. S. Chung, “High-brightness light emitting diodes using dislocation-free Indium gallium nitride/gallium nitride multi-quantum-well nano-rod arrays,” Nano Letters 4, 2004, pp. 1059-1062.

[8] A. Kikuchi, M. Kawai, M. Tada and K. Kishino, “InGaN/GaN Multiple Quantum Disk Nanocolumn Light-Emitting Diodes Grown on (111) Si Substrate,” Japanese Journal of Applied Physics, Vol. 43, No. 12A, 2004, pp. L1524-L1526.

[9] T. H. Hsueh, H. W. Huang, C. C. Kao, Y. H. Chang, M. C. Ou-Yang, H. C. Kuo, S. C. Wang, “Characterization of InGaN/GaN MQW nano-rods fabricated by plasma etching with self-assembled nickel metal nanomask,” Japanese Journal of Applied Physics, Vol. 44, 2005, pp. 2661-63.

[10] L. Chen, A. Yin, J. S. Im, A. V. Murmikko, J. M. Xu, J. Han, “Fabrication of 50-100nm patterned InGaN blue light emitting heterostructures,” Phys. Stat. Sol. (A), 188, 2001, pp. 135-8.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method of fabricating a semiconductor device, comprising:
merging semiconductor nano-rods in a nano-rod array through coalescence into a continuous planar layer after fabrication of the nano-rods.

2. The method of claim 1, wherein the merging step comprises merging the nano-rods through coalescence into the continuous planar layer by tuning conditions to promote epitaxial lateral overgrowth.

3. The method of claim 1, further comprising fabricating the nano-rods by growth.

4. The method of claim 3, wherein the nano-rods are grown on top of an n-type layer, an active region is deposited on top of the nano-rods, and a p-type layer is grown on top of the active region, wherein the p-type layer is coalesced into the continuous planar layer.

5. The method of claim 4, wherein the active region is protected by a capping layer with a higher bandgap than the active region.

6. The method of claim 5, wherein a masking layer is deposited before the capping layer, so that the nano-rods are not covered by the capping layer.

7. The method of claim 1, further comprising fabricating the nano-rods by etching.

8. The method of claim 7, wherein the nano-rods are etched from an initially planar epitaxial structure comprised of an n-type layer, an active region deposited on top of the n-type layer, and a p-type layer grown on top of the active region.

9. The method of claim 8, wherein the active region is protected by a capping layer with a higher bandgap than the active region.

10. The method of claim 9, wherein a masking layer is deposited before the capping layer, so that the nano-rods are not covered by the capping layer.

11. The method of claim 7, further comprising annealing the etched nano-rods.

12. The method of claim 11, wherein the p-type layer is coalesced into the continuous planar layer after the nano-rods are annealed.

13. The method of claim 1, wherein the nano-rods comprise pillars with non-planar tips.

14. The method of claim 1, wherein the nano-rods are wafer-bonded to another wafer or substrate.

15. The method of claim 1, wherein the nano-rod array comprises a photonic crystal.

16. The method of claim 1, wherein individual ones of the nano-rods within the nano-rod array emit light of different wavelengths.

17. A device manufactured according to the method of claim 1.

18. A method of fabricating a semiconductor device, comprising:
(a) depositing a conducting (Al,Ga)N nucleation layer on a substrate in a growth chamber, followed by the deposition of a n-type GaN:Si layer;
(b) removing the substrate from the growth chamber and depositing a SiO₂ layer onto the nucleation layer, wherein the SiO₂ layer is patterned using lithographic techniques to create an array of openings in the SiO₂ layer;
(c) transferring the substrate back into the growth chamber, and selectively growing n-type semiconductor nano-rods in the array of openings, and growing an InGaN/GaN quantum well (QW) active region on the n-type semiconductor nano-rods; and
(d) growing a p-type GaN:Mg layer with a larger band gap than the QW active region on top of the QW active region, wherein, during the growth of the p-type GaN:Mg layer, deposition conditions enhance lateral growth and coalescence of the p-type GaN:Mg layer, thereby merging the nano-rods through coalescence into a continuous planar layer.

19. A device manufactured according to the method of claim 18.

20. A method of fabricating semiconductor devices, comprising:
(a) depositing a conducting (Al,Ga)N nucleation layer on a substrate in a growth chamber, followed by a deposition of an n-type GaN:Si layer, InGaN/GaN quantum well (QW) active region, and a p-type GaN:Mg layer;
(b) removing the substrate from a growth chamber and depositing a SiO₂ layer onto the p-type GaN:Mg layer, wherein the SiO₂ layer is patterned using lithographic techniques to create an array of openings in the SiO₂ layer;
(c) transferring the substrate into an etching chamber, and forming n-type semiconductor nano-rods in the array of openings; and
(d) transferring the substrate into the growth chamber, and growing a p-type GaN:Mg layer on the n-type semiconductor nano-rods, wherein, during the growth of the p-type GaN:Mg layer, deposition conditions promote lateral growth and coalescence of the p-type GaN:Mg layer, thereby merging the nano-rods through coalescence into a continuous planar layer.

21. A device manufactured according to the method of claim 20.
